(19) United States
(12) Patent Application Publication
(10) Pub. No.: US 2008/0176394 A1
(43) Pub. Date: Jul. 24, 2008

(54) Method for manufacturing semiconductor device

(75) Inventor: Tae Young Lee, Seongnam-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu HiTek Co., Ltd.

(21) Appl. No.: 11/980,657

(22) Filed: Oct. 31, 2007

(30) Foreign Application Priority Data
Dec. 27, 2006 (KR) 10-2006-0135772

(51) Int. Cl. H01L 21/4763

(52) U.S. Cl. 438/618; 257/E21.495

(57) ABSTRACT

A method for manufacturing a semiconductor device is provided. The method may include forming a metal interconnection on a substrate, forming a liner layer on the substrate including the metal interconnection, performing a plasma process to an entire surface of the substrate including the liner layer, and forming a dielectric film on the plasma-processed liner layer.

The present application claims the benefit of priority under 35 U.S.C. § 119 to Korean Patent Application No. 10-2006-0135772, filed on Dec. 27, 2006, the entire contents of which are incorporated herewith by reference.

### BACKGROUND

The present invention relates generally to a method for manufacturing a semiconductor device, and more particularly, to a method for manufacturing a semiconductor device having metal interconnections.

The integration of semiconductor devices increases the number of metal interconnections in semiconductor devices, and decreases pitches of the metal interconnections. The reduction in the pitches of the metal interconnections not only increases the resistance of the metal interconnections, but also causes an inter-metal dielectric (IMD) layer between the metal interconnections. The IMD layer insulates the metal interconnections of the semiconductor devices and, together with the metal interconnections, forms a parasitic capacitor structure. Accordingly, electrical properties of the semiconductor devices may be deteriorated. For example, the RC constant, which determines the response speed of a semiconductor device, may be increased, and the power consumption of the semiconductor device may also be increased.

In order to solve such problems, a low-k IMD layer, which is suitable for high integration of semiconductor devices, has been employed. Recently, for example, a fluorine-doped silicate glass (FSG) layer has been used as a low-k IMD layer. In general, a lower fluorine density in the FSG layer causes the FSG layer to have a lower dielectric constant and a higher degree of bonding with moisture. The higher degree of moisture bonding with the FSG layer may cause corrosion to the metal interconnections. Accordingly, there is a trade-off between the lower dielectric constant and the higher degree of moisture bonding of the FSG layer. For this reason, a FSG layer having a relatively high dielectric constant of about 3.5 has been generally used.

According to the related art, the FSG layer has excellent gap-fill characteristics, but free fluorine existing in the FSG layer causes various side effects. Among the side effects, corrosion of metal interconnections is the most representative one.

### SUMMARY

Embodiments consistent with the present invention provide a method for manufacturing a semiconductor device. The method can improve adhesion property between a metal interconnection and a dielectric film of the semiconductor device.

In one embodiment, there is provided a method for manufacturing a semiconductor device, the method comprising: forming a metal interconnection on a substrate; forming a liner layer on the substrate including the metal interconnection; performing a plasma process to an entire surface of the substrate including the liner layer; and forming a dielectric film on the plasma-processed liner layer.

In another embodiment, there is provided a method for manufacturing a semiconductor device, the method comprising: forming a first dielectric film on a substrate having a metal interconnection; forming a first silicon rich oxide (SRO) layer on the first dielectric film; performing a plasma process to an entire surface of the substrate including the first SRO layer; and forming a second dielectric film on the plasma-processed first SRO layer.

### BRIEF DESCRIPTION OF THE DRAWINGS

FIG. 1 is a sectional view illustrating a method for manufacturing a semiconductor device according to a first embodiment consistent with the present invention;

FIG. 2 is another sectional view illustrating a method for manufacturing a semiconductor device according to a first embodiment consistent with the present invention;

FIG. 3 is a diagram showing the effect of a method for manufacturing a semiconductor device according to an embodiment; and

FIG. 4 is a sectional view illustrating a method for manufacturing a semiconductor device according to a second embodiment consistent with the present invention.

### DETAILED DESCRIPTION

Hereinafter, a method for manufacturing a semiconductor device according to an embodiment consistent with the present invention will be described in detail with reference to the accompany drawings.

It will be understood that when a layer (or a film) is referred to as being ‘on’ another layer or substrate, it can be directly or indirectly on another layer or substrate, that is, intervening layers may be present. Further, when a layer is referred to as being ‘under’ another layer, it can be directly or indirectly under another layer, that is, one or more intervening layers may be present. In addition, it will also be understood that when a layer is referred to as being ‘between’ two layers, it can be the only layer between the two layers, or one or more intervening layers may be present.

### FIRST EMBODIMENT

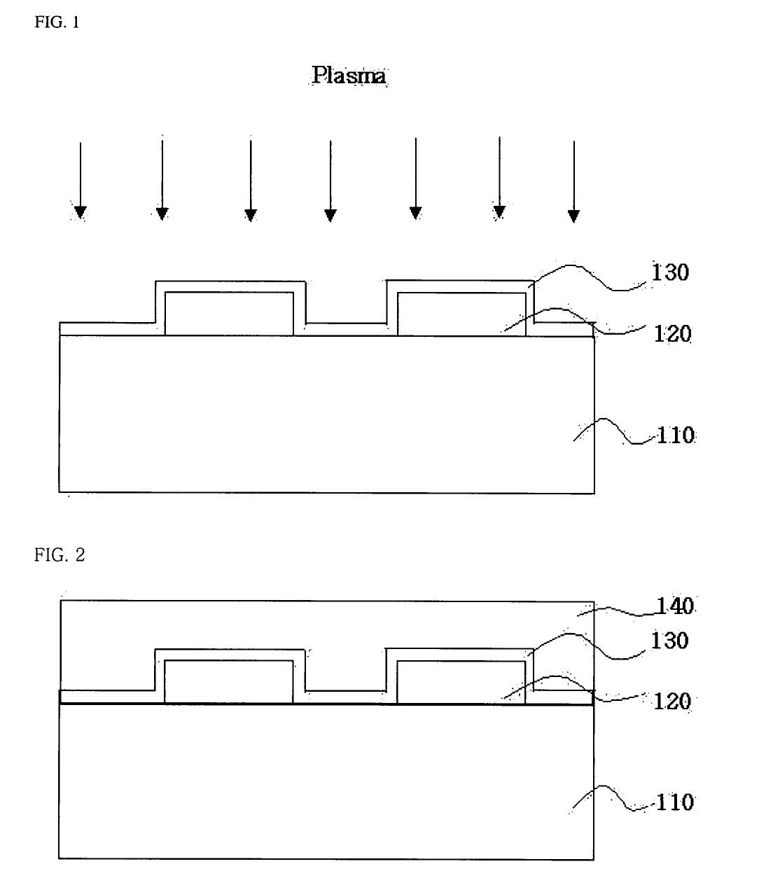

FIGS. 1 and 2 are sectional views illustrating a method for manufacturing a semiconductor device, according to a first embodiment consistent with the present invention.

First, a metal interconnection 120 is formed on a substrate 110. Metal interconnection 120 may comprise aluminum, copper, and the like.

Then, a liner layer 130 is formed on substrate 110 including metal interconnection 120. In one embodiment, liner layer 130 may comprise a silicon rich oxide (SRO) layer.

In order to form SRO layer 130, substrate 110 may be inserted into, for example, a chemical vapor deposition (CVD) apparatus, such as a plasma-enhanced chemical vapor deposition (PECVD) apparatus or a high density plasma chemical vapor deposition (HDP-CVD) apparatus. The CVD apparatus may be operated at a radio frequency (RF) power of about 2,000 W to 5,000 W and supplied with a SiH₄ gas flow of about 80 sccm to 150 sccm, an O₂ gas flow of about 100 sccm to 2000 sccm, and an Ar gas flow of about 50 sccm to 100 sccm.

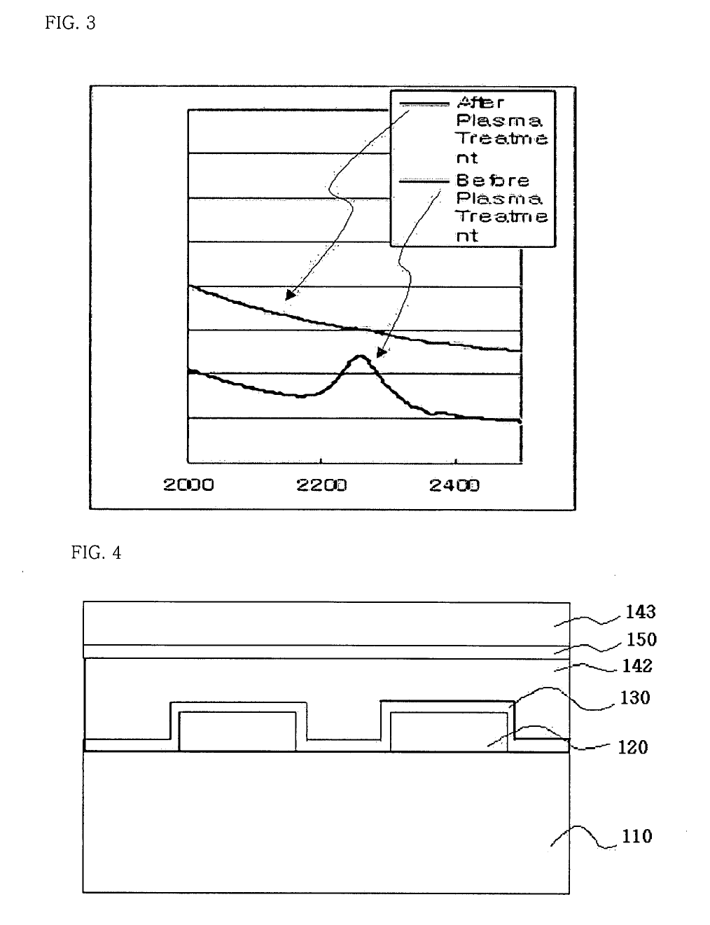

Next, a plasma process is performed to the entire surface of substrate 110 including SRO layer 130. Because poor adhesion property of SRO layer 130 may be caused by excessive Si—H bondings existing on the surface of SRO layer 130 or in the bulk of SRO layer 130, the Si—H bondings may be inspected through a Fourier transform infra-red (FTIR) spectrum (see FIG. 3). Such Si—H bonding is a weak hydrogen bonding as compared with the bondings of F-H, O-H, and N-H that are elements in another dielectric film. However, an O-H group has a superior adhesion due to its strong hydrogen bonding. Accordingly, the plasma process may improve the weak hydrogen bonding due to the presence of Si—H bonding on the surface of SRO layer 130.

The plasma process may employ a plasma furnace to cause surface oxidation and to form an OH bonding structure on the surface of SRO layer 130 through an O₂ plasma process. In one embodiment, the O₂ plasma process may be performed under the condition of a time period of about 60 seconds to 80 seconds, a pressure of about 8 Torr to 10 Torr, an RF power of about 400 W to 600 W (HF), a temperature of about 300° C. to 500° C., an O₂ flow rate of about 800 sccm to 1,200 sccm, and a spacing of about 220 mils to 260 mils.

According to another embodiment consistent with the present invention, strong hydrogen bondings of O—H or N—H, instead of the Si—H bonding, can be formed on the surface of SRO layer 130 through a plasma process using N₂O or a mixed gas of N₂O and N₂. In one embodiment, the mixed gas plasma may be formed under the condition of a time period of about 60 seconds to 80 seconds, a pressure of about 2.25 Torr to 2.65 Torr, an RF power of about 300 W to 400 W (HF), a temperature of about 300° C. to 500° C., a N₂O flow rate of about 3,600 sccm to 4,000 sccm, and a N₂ flow rate of about 3,600 sccm to 4,000 sccm. After SRO layer 130 is formed, a dielectric film 140 is formed on plasma-processed SRO layer 130 as shown in FIG. 2.

FIG. 3 is a diagram showing the effect of the method for manufacturing the semiconductor device according to the embodiments. FIG. 3 shows a comparison result of FTIR spectra obtained from the surface of SRO layer 130 before and after the plasma process is performed. In FIG. 3, the X-axis (horizontal) represents the infra-red wavelengths (in unit of Å) of the FTIR spectrum.

As can be seen from FIG. 3, before the plasma process including the O₂ gas or the mixed gas of N₂O and N₂, a peak of Si—H bonding occurs. However, after the plasma process is performed, the peak of Si—H bonding no longer exists. Accordingly, the adhesion of SRO layer 130 may be improved and the peeling defect of dielectric film 140 may disappear. That is, as can be seen from FIG. 3, the peak of Si—H bonding causing poor adhesion between SRO layer 130 and dielectric film 140 disappears through the plasma process.

Further, such Si—H bonding may be converted into Si—OH bonding. Accordingly, the adhesion of SRO layer 130 may be improved, so that the peeling defect of dielectric film 140 may disappear.

Alternatively, after forming metal interconnection 120 on substrate 110, a lower dielectric film (not shown) may be formed on substrate 110 including metal interconnection 120. A plasma process may be performed to the lower dielectric film. Accordingly, the lower dielectric film may be formed to have a surface having a strong hydrogen bonding of Si—OH, O—H, or N—H through oxidation or nitration of the lower dielectric film. Therefore, adhesion of the lower dielectric film with SRO layer 130 to be formed later can be improved. Thus, adhesion between layers of the semiconductor device can be improved significantly.

### SECOND EMBODIMENT

FIG. 4 is a sectional view showing a method for manufacturing a semiconductor device according to a second embodiment consistent with the present invention. As shown in FIG. 4, a metal interconnection 120 is formed on a substrate 110. Metal interconnection 120 may comprise aluminum, copper, and the like.

Then, a liner layer 130 is formed on substrate 110 including metal interconnection 120. In one embodiment, liner layer 130 may comprise a first SRO layer.

A plasma process may be performed to the entire surface of substrate 110, on which first SRO layer 130 is formed, and a second dielectric film 142 is formed on plasma-processed first SRO layer 130.

In one embodiment, after forming second dielectric film 142, a second SRO layer 150 may be formed on second dielectric film 142, a plasma process may be performed to the entire surface of substrate 110, on which second SRO layer 150 is formed, and a third dielectric film 143 may be formed on plasma-processed second SRO layer 150.

In the second embodiment consistent with the present invention, the plasma process is introduced to improve the weak hydrogen bonding of Si—H bonding existing on the surfaces of first SRO layer 130 and second SRO layer 150, as explained previously.

The plasma furnace used in the plasma process can cause surface oxidation on first and second SRO layers 130 and 150, and form an OH bonding structure on the surface of first and second SRO layers 130 and 150 through an O₂ plasma process. In one embodiment, the O₂ plasma process may be performed under the condition of a time period of about 60 seconds to 80 seconds, a pressure of about 8 Torr to 10 Torr, an RF power of about 400 W to 600 W (HF), a temperature of about 300° C. to 500° C., an O₂ flow rate of about 800 sccm to 1,200 sccm, and a spacing of about 220 mils to 260 mils.

Further, strong hydrogen bonding of O-H or N-H, instead of the Si—H bonding, can be formed on the surfaces of first and second SRO layers 130 and 150 through the plasma process using a N₂O gas or a mixed gas of N₂O and N₂. In one embodiment, the mixed gas plasma process may be performed under the condition of a time period of about 60 seconds to 80 seconds, a pressure of about 2.25 Torr to 2.65 Torr, an RF power of about 300 W to 400 W (HF), a temperature of about 300° C. to 500° C., a N₂O flow rate of about 3,600 sccm to 4,000 sccm, and a N₂ flow rate of about 3,600 sccm to 4,000 sccm.

According to the second embodiment consistent with the present invention, before the plasma process including the O₂ gas or the mixed gas of N₂O and N₂, a peak of Si—H bonding occurs, as shown in FIG. 3. However, after the plasma process is performed, the peak of Si—H bonding no longer exists. Accordingly, the adhesion of first and second dielectric films 142 and 143 with first and second SRO layers 130 and 150 may be improved, and the peeling defect of second and third dielectric films 142 and 143 may disappear or reduce substantially.

Alternatively, after forming metal interconnection 120 on substrate 110, a first dielectric film (not shown) may be formed on substrate 110, and a plasma process may be performed to the first dielectric film. Accordingly, the first dielectric film may have a surface having a strong hydrogen bonding of Si—OH, O—H, or N—H through oxidation or nitration of the first dielectric film. Therefore, adhesion of the first dielectric film with first SRO layer 130 to be formed later can be improved. Thus, adhesion between layers of the semiconductor device can be improved significantly.

As described above, the plasma process performed to the SRO layers can improve the adhesion property of the SRO layers with the dielectric films. Thus, the peeling defect of the dielectric films can be eliminated or reduced substantially. Further, because the adhesion property between the SRO layers and the dielectric films is improved, the reliability and yield rate of the semiconductor device is also improved.

Although embodiments consistent with the present invention have been described in detail with reference to the accompanying drawings, it should be understood that numerous other modifications and embodiments can be devised by those skilled in the art without departing from the spirit and scope of the principles of this disclosure. More particularly, various variations and modifications are possible in the component parts and/or arrangements of the subject combination arrangement within the scope of the appended claims. In addition to variations and modifications in the component parts and/or arrangements, alternative uses will also be apparent to those skilled in the art.

What is claimed is:

1. A method for manufacturing a semiconductor device, the method comprising:
forming a metal interconnection on a substrate;
forming a liner layer on the substrate including the metal interconnection;
performing a plasma process to an entire surface of the substrate including the liner layer; and
forming a dielectric film on the plasma-processed liner layer.

2. The method as claimed in claim 1, wherein the liner layer comprises a silicon rich oxide (SRO) layer.

3. The method as claimed in claim 1, further comprising:
forming a lower dielectric film on the substrate including the metal interconnection; and
performing the plasma process to the lower dielectric film.

4. The method as claimed in claim 2, further comprising:
forming a lower dielectric film on the substrate including the metal interconnection; and
performing the plasma process to the lower dielectric film.

5. The method as claimed in claim 1, wherein the plasma process includes an O₂ plasma process.

6. The method as claimed in claim 3, wherein the plasma process performed to the substrate includes an O₂ plasma process.

7. The method as claimed in claim 1, wherein the plasma process includes a N₂O plasma process.

8. The method as claimed in claim 3, wherein the plasma process performed to the substrate includes a N₂O plasma process.

9. The method as claimed in claim 1, wherein the plasma process includes a plasma process using a mixed gas of N₂ and N₂O.

10. The method as claimed in claim 3, wherein the plasma process performed to the substrate includes a plasma using a mixed gas of N₂ and N₂O.

11. A method for manufacturing a semiconductor device, the method comprising:
forming a first dielectric film on a substrate having a metal interconnection;
forming a first silicon rich oxide (SRO) layer on the first dielectric film;
performing a plasma process to an entire surface of the substrate including the first SRO layer; and
forming a second dielectric film on the plasma-processed first SRO layer.

12. The method as claimed in claim 11, further comprising performing the plasma process to the first dielectric film.

13. The method as claimed in claim 11, wherein the plasma process performed to the entire surface of the substrate includes an O₂ plasma process.

14. The method as claimed in claim 11, wherein the plasma process performed to the entire surface of the substrate includes an N₂ plasma process.

15. The method as claimed in claim 11, wherein the plasma process performed to the entire surface of the substrate includes a plasma process using a mixed gas of N₂ and N₂O.

16. The method as claimed in claim 12, wherein the plasma process performed to the first dielectric film includes an O₂ plasma process.

17. The method as claimed in claim 12, wherein the plasma process performed to the first dielectric film includes an N₂ plasma process.

18. The method as claimed in claim 12, wherein the plasma process performed to the first dielectric film includes a plasma process using a mixed gas of N₂ and N₂O.

19. The method as claimed in claim 11, further comprising:
forming a second SRO layer on the second dielectric film;
performing the plasma process to the second SRO layer; and
forming a third dielectric film on the plasma-processed second SRO layer.

20. The method as claimed in claim 12, further comprising:
forming a second SRO layer on the second dielectric film;
performing the plasma process to the second SRO layer; and
forming a third dielectric film on the plasma-processed second SRO layer.
